(19) United States
(12) Patent Application Publication
(10) Pub. No.: US 2012/0080080 A1
(43) Pub. Date: Apr. 5, 2012

(54) METHODS AND SYSTEMS FOR CONTROLLING IMAGE CHARACTERISTICS OF A WINDOW

(76) Inventor: Hanoch SHALIT, Nicosia (CY)

(21) Appl. No.: 13/242,977

(22) Filed: Sep. 23, 2011

Related U.S. Application Data
(60) Provisional application No. 61/388,758, filed on Oct. 1, 2010.
(60) Provisional application No. 61/391,306, filed on Oct. 8, 2010.

(51) Int. Cl. H01L 31/04; G02B 27/12; G02B 5/22

(52) U.S. Cl. 136/252; 359/885; 359/639

(57) ABSTRACT

A window with variable transparency to light, the window includes at least two layers, the layers being arranged parallel to one another. Each layer includes a pattern of a plurality of alternating transparent and nontransparent areas. At least one of the layers is movable back and forth in one direction so as to vary the transparency of the window.

### CROSS REFERENCE TO RELATED APPLICATIONS

The present invention claims the priority benefit of U.S. provisional patent application No. 61/388,758 filed on Oct. 1, 2010, of U.S. provisional patent application No. 61/391,306 filed on Oct. 8, 2010, which are incorporated in their entirety herein by reference.

### FIELD OF THE INVENTION

The present invention relates to systems controlling light passage through a transparent medium, such as a window or partition.

### BACKGROUND OF THE INVENTION

The past few decades have seen widespread use of multilayer window glass panes to meet growing demands for highly air-tight, thermally insulated houses. For the purpose of increasing thermal insulating performance multilayer glass panes are used. In order to provide privacy the clear (transparent) glass has been made matte or translucent using high pressure sanding methods or chemical etching techniques. In a more sophisticated method to achieve similar goal of translucent glass at will (e.g., at the push of a button), liquid crystal display (LCD) panel systems and methods were used. These systems require electric circuitry to provide energy to the system to modify the properties of an internal material within the system, and thus the optical properties of the whole system. These systems require sophisticated production methods and equipment, making the final product very expensive to produce, install, and use.

The materials used for current state-of-the-art products, and the required expensive means of production, make these products very expensive to produce, install and use. In addition, they may be subject to size limitations, e.g., they cannot be produced above a certain size, and the size has to be predetermined during production and cannot be modified by the installer at the customer site.

To make a window pane an energy saver, a high priority is usually given to efforts to reduce the light and heat energy passing through it to the building interior. For reducing the air-conditioning system load, heat reflecting glass panels were widely used. They may include one or more layers of a metal oxide, a metal, and a metal nitride on a transparent glass sheet. Such conventional heat reflecting glass panels may be highly effective in reducing air-conditioning system load because they have good sunlight shielding performance (e.g. triple silver layer low emissivity film structure). However, the light shielding and transmission is constant—unaffected by the outside conditions and the customer's will.

Another technique employed is the use of photochromic materials that reduce incoming light intensity. An example of such system is the use of silver halide materials within a medium of glass. When sunlight hits the silver halide crystals, it generates metallic silver from the silver ions, and turns the crystals from a transparent medium to black, effectively darkening the glass in the process. This process is reversible, as the halide hole, which is part of the reduction reaction, may combine again with the silver atoms in the crystal when light intensity is reduced. Such a system is very expensive to produce and does not allow modification of light intensity by the consumer: light itself activates the process and the medium darkens proportionally to the amount of light energy illuminating it.

All the current state-of-the-art products and discussed systems are very expensive to produce and to install. Most require electrical current to operate and hence the pane has to be near a source of electricity.

### SUMMARY OF THE INVENTION

It is therefore an object of the present invention to provide a system and method that allows control and modification of light properties in a medium such as a window or a door. To allow alteration the light properties, at will, from a clear transparent medium, through which the image of the scenery through the medium is clearly visible, to, for example, a translucent medium where the light from the image is scattered such that the image cannot be clearly seen, or, in another example, to a reduced transmission of the light (or heat or other radiation) passing through. The system, in one embodiment, includes two layers having alternating transparent and translucent parallel lines or areas of equal width. These layers allow clear image to be seen when the transparent (and the translucent) lines of the two layers superimpose (respectively). Moving mechanisms are proposed to move one layer over the other. When the translucent lines are moved over the transparent, the total visible area (e.g., the window) becomes translucent, thus scattering the image light. Using this system it is possible to have, at will, a window pane that is transparent, while when privacy is desired, the layers can be moved such that the whole window becomes translucent.

It is also a characteristic of the proposed system, that is has the properties of diffusely reflecting or diffusely transmitting intentionally projected images on it, so that they can be seen by the human eye.

The transparent sheet may comprise a glass or other clear material sheet which is transparent or semitransparent in a visible light wavelength range or a synthetic resin sheet which is transparent or semitransparent in a visible light wavelength range. The glass sheet may be made of, for example, float glass, soda-lime glass, 45 borosilicate glass, or crystallized glass. The synthetic resin sheet may be made of, for example, PET (polyethylene terephthalate), PVB (polyvinyl butyral), EVA (ethylenevinyl acetate copolymer), or a cellulose resin. Generally, the transparent sheet may have a thickness which should range preferably from 0.0001 mm to 30 mm, more preferably from 0.1 mm to 10 mm. Other ranges and sizes may be used.

The transparent medium can be the substrate of the transparent sheet. This substrate is capable of transferring image forming light, mainly unaffected, in some applications described here. It should preferably have a visible light transmittance ranging from 10% to 100%, more preferably from 70% to 100%. However, the transparent medium may be an add-on medium to the substrate, such as a synthetic resin laminate. Preferably, the add-on transparent medium may have a thickness ranging from 0 mm (e.g. it may be absent, a void in a clear empty window) to 10 mm, preferably from 0 to 2 mm. Other ranges and sizes may be used.

The translucent medium can be the substrate of the transparent sheet, which was treated to become translucent, and is capable of scattering the incoming image forming light, so as to scatter and diffuse an image so that it may not be clearly seen by the human eye. It should preferably have a visible light transmittance ranging from 10% to 100%, more preferably from 70% to 100%. The treatment of the transparent sheet into the translucent state can be done by, for example in the case of glass, chemical etching or sand blasting.

However, the translucent medium may be an add-on medium to the substrate, such as a synthetic resin laminate. Preferably, the add on translucent medium may have a thickness ranging from 0.01 mm to 10 mm, preferably from 0.1 mm to 2 mm. Other ranges and sizes may be used.

In one embodiment of the invention, the two layers (or panels) have alternate parallel lines of transparent and translucent media, respectively. The lines may have a width ranging from 0.001 mm to 30 cm, preferably from 0.01 to 2 mm. Other ranges and sizes may be used. When the two panels are put near each other such that the transparent lines of each panel are in phase, e.g., where the transparent lines of one panel are superimposed on the transparent lines of the other panel and the translucent lines of one panel are superimposed on the translucent lines of the other panel, a clear image of the scenery is seen by the human eye. However, when one panel is moved so that its transparent lines are over the translucent lines of the other panel the image becomes less clear. When the panel is moved such that most or all of its transparent lines are over the translucent lines of the other panel, the clear image may be replaced by a scattered (diffused) image showing only very rough outline of the observed scene, if any.

In another embodiment of the invention, the two panels have alternate parallel areas, e.g., squares or parallelograms, of transparent and nontransparent (e.g. translucent) media, respectively. The areas may have a size ranging from 0.000001 mm² to 900 cm², preferably from 0.0001 mm² to 4 cm². The pattern may include regularly spaced alternating transparent and nontransparent (e.g. translucent) geometrical shapes of areas ranging from 100 μm² to 1 m². Other ranges and sizes may be used. When the two panels are put near each other such that the transparent areas of each panel are in phase, e.g., where the transparent areas of one panel are superimposed on the transparent areas of the other panel and the translucent areas of one panel are superimposed on the translucent areas of the other panel, a clear image of the scenery is seen by the human eye. However, when one panel is moved so that its transparent areas are over the translucent areas of the other panel the image becomes less clear. When the panel is moved such that most or all of its transparent areas are over the translucent areas of the other panel, the clear image may be replaced by a scattered (diffused) image showing only very rough outline of the observed scene, if any.

In another embodiment of the invention, the two panels have alternate parallel areas, e.g., parallelograms (e.g. squares or rectangles) of transparent and translucent (or other nontransparent) media, respectively. The areas may have a size ranging from 0.000001 mm² to 900 cm², preferably from 0.0001 mm² to 4 cm². Alternatively, the transparent medium of one panel has a color that is different from the other medium of the same panel. Alternatively, the transparent medium of one panel has a color that is different from the similar medium of the other panel and/or the other medium in the other panel. When the two panels are put near each other such that the transparent areas of each panel are in phase, e.g., where the transparent areas of one panel are superimposed on the transparent areas of the other panel and the translucent areas of one panel are superimposed on the translucent areas of the other panel, a clear image of the scenery is seen by the human eye. This image has a distinct color resulting from the combination of the colors of the various media. However, when one panel is moved so that its transparent areas are over the translucent areas of the other panel the image becomes less clear. When the panel is moved such that most or all of its transparent areas are over the translucent areas of the other panel, the clear image may be replaced by a scattered (diffused) image showing only very rough outline of the observed scene. This translucent image may have a color that is different than the color of the transparent image, depending on the combinations of colors in the various media and their positions.

In another embodiment the color in the transparent and in the translucent areas is the same.

Embodiments of the current invention are different than the current state of the art in that they may provide a different methodology and a different system to transmit a clear image and change it, at will, to a scattered or lower intensity image. Embodiments may not require electrical energy to apply to the light modulating medium, and cost of production may be lower.

In one embodiment, the light transmission is modified by a system that includes two glass panes each having alternate parallel lines of clear (transparent) and high optical density material, and the parallel lines of one layer are also parallel to the other layer. One layer is moved by a small distance over the other layer. When the transparent areas in both layers overlap (and so do the high optical density areas, respectively), the scene image through the pane is clearly visible, while when the high optical density areas in both layers cover the whole area of the glass pane, it becomes very dark. This controls incoming image clarity and light intensity, as well as energy intensity, distribution and amounts.

The surface of the high optical density (opaque or black) areas that faces the sun can be made to be reflective so that it may reflect, rather than absorb, the incoming energy, reducing the heat load on the building interiors. A surface of the high optical density areas that is intended to face the sun can be made to be selectively reflective and absorbing to different regions of the incident spectrum. Thus, in one example, it may reflect the heat but absorb in the visible region of the spectrum. Thus, heat load on the building interior may be reduced, and the area may appear colored or tinted to the human eye. The selective reflective and absorbing properties of the layer can be designed to be different for the section of the layer that faces the exterior than for that facing the interior of the building. For example, the section facing the exterior can be made to mainly reflect heat and absorb one section of the visible section, e.g. absorb magenta to appear green, while an interior section can be designed to absorb heat and a different section of the visible spectrum, e.g. absorb yellow so as to appear blue. Thus, during the summer, the exterior facing layer reflects the heat, cooling the interior of the building, while the internal section absorbs the room heat. When the window is turned around in the winter, the exterior facing sections of the layer would absorb the sun heat, warming the building interior, while the section facing the interior reflects the room heat back to the interior, preserving heat.

In another embodiment, using the layout of the layout of current double-glazing windows, sheets of opaque or nontransparent material are attached to the glasses, perpendicular to the glass pane. When one of the glass panes is moved, there is reduction in incoming light intensity.

Similarly, if the material of perpendicular sheets is translucent, moving the pane may reduce incoming image clarity, and increase window translucency.

### BRIEF DESCRIPTION OF THE DRAWINGS

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1 schematically shows an example of a layer of parallel lines of transparent and translucent areas on a transparent substrate according to an embodiment of the invention.

FIG. 2 schematically shows a side view of the layer in FIG. 1.

FIG. 3 schematically shows an illustration of the light passage through two layers producing a clear image according to an embodiment of the invention.

FIG. 4 schematically shows an illustration of the light passage through the out of phase layers producing no clear image according to an embodiment of the invention.

FIG. 5 schematically shows an example of a design pattern of the transparent and translucent areas on a layer according to an embodiment of the invention.

FIG. 6 schematically shows an example of a mechanical activation mechanism, using a wedge, when the layer is moved to an out of phase position according to an embodiment of the invention.

FIG. 7 schematically shows an example of a mechanical activation mechanism, using a wedge, when the layer is in an in-phase position according to an embodiment of the invention.

FIG. 8 schematically shows an example of a mechanical activation mechanism, using an elliptical dial, when the layer is moved to an out of phase position according to an embodiment of the invention.

FIG. 9 schematically shows an example of side view of the two layers side by side with areas of high optical density material, with their transparent and dark areas superimposed according to an embodiment of the invention.

FIG. 10 schematically shows the two layers, as in FIG. 9, where the high optical density (opaque) areas cover the transparent areas such that no light (or reduced intensity light) is passing through, with the external side of the opaque material including heat reflectors according to an embodiment of the invention.

FIG. 11 schematically shows a combined system of four layers containing transparent, translucent, and opaque areas according to an embodiment of the invention.

FIG. 12 schematically shows combined system of three layers containing transparent, translucent, and opaque areas according to an embodiment of the invention.

FIG. 13 schematically shows combined system of two layers containing transparent, translucent, and opaque areas according to an embodiment of the invention.

FIG. 14 schematically shows photovoltaic material coated on the high optical density areas of the layers according to an embodiment of the invention.

FIG. 15 schematically shows an example of a wide gap between the layers that causes a partial image to be seen when the system is in a translucent mode according to an embodiment of the invention.

FIG. 16 schematically shows an example of a design of a standard double glazing window, modified to add a layer of transparent and translucent areas, and an additional layer of transparent and translucent areas, where the two layers are in phase according to an embodiment of the invention.

FIG. 17 schematically shows an example of a design of a standard double glazing window, modified to add a layer of transparent and translucent areas, and an additional layer of transparent and translucent areas, where the two layers are out of phase according to an embodiment of the invention.

FIG. 18 schematically shows a moving mechanism for a layer according to an embodiment of the invention.

FIG. 19 schematically shows an example of producing a translucent layer of translucent ink on a transparent substrate using flexographic printing according to an embodiment of the invention.

FIG. 20 schematically shows an example of producing a translucent layer of translucent ink on a transparent substrate using inkjet printing according to an embodiment of the invention.

FIG. 21 schematically shows an example of producing a translucent layer of translucent ink on a transparent substrate using inkjet printing, where the printing heads are also aligned behind each other to allow for narrower gap between the lines according to an embodiment of the invention.

FIG. 22 shows printing (depositing) laminated optically modifying material on a transparent pane according to an embodiment of the invention.

FIG. 23 shows a front view of an insulating layer between the stationary and the moving layers to avoid dirt and obstacles to get into the space between the glass layers according to an embodiment of the invention.

FIG. 24 shows a side view of the insulating layer shown in FIG. 23.

FIG. 25 illustrates scattering by panels with lenses according to an embodiment of the invention.

FIG. 26 shows the panels of FIG. 25 aligned such that lens on the panels compensate for one another according to an embodiment of the invention.

### DETAILED DESCRIPTION OF EMBODIMENTS

Systems and methods for controlling light transmission through the glass pane of openings such as window and doors or any other window in buildings or vehicles are disclosed. In accordance with embodiments of the invention, the light transmission is modified by a window that includes a glass pane with two parallel (or substantially parallel) layers or panels (the terms “layer” and “panel” are used herein interchangeably) each having a pattern of transparent areas and nontransparent areas. Transparent is used herein to refer to a region that transmits directly at least part of the visible spectrum (e.g. may include spectrally selectively transmissive materials such as tinted or colored transparent materials). Nontransparent is used herein to refer to a region that is opaque (reflecting or absorbing) to a region of the visible spectrum which the transparent region transmits, or is translucent (matte, textured, or scattering) to a region of the visible spectrum. The layers may be moved back and forth relative to one another so as to modify the alignment of the transparent and nontransparent areas of the two layers, thus modifying the transmission properties of the window.

For example, the layers may include alternating areas or stripes of transparent and nontransparent materials, or alternating parallelograms (e.g. rectangles) of transparent and nontransparent materials. The sizes of the areas or stripes or parallelograms may be uniform across the area of the layer, or may vary in a regular manner. Shapes other than parallelograms or stripes may be used. The dimensions of the stripes or parallelograms may be selected to avoid visible wave interference or diffraction effects in the transmitted light. Similarly, dimensions and alignment may be controlled so as to avoid any visible moiré effects or similar pattern interference effects when the layers are superimposed. For example, a typical stripe width or rectangle side may be in the range of about 10 micrometers to about 1000 micrometers.

In one embodiment, the light transmission is modified by a system that includes a glass pane with two glass layers or panels each having alternate parallel lines of clear (transparent) and matte (translucent) material, and the parallel lines of one layer are also parallel to the lines of the other layer. One layer is moved by a small distance over the other layer. When the transparent areas in both layers overlap (as do the matte areas), the scene image as viewed through the pane is clearly visible. On the other hand, when the translucent areas in both layers cover the whole area of the glass pane, it becomes translucent. This controls incoming image clarity and light scatter, as well as energy intensity, distribution and amounts. Similarly, when the translucent lines are replaced with black (high-density) lines, the glass pane can become opaque. In a similar embodiment, an image can be projected onto the pane in any configuration (transparent, translucent or any stage in between), allowing the projected image to be visible from either side of the glass panes or layers. In another embodiment, the material that makes up the nontransparent line can have reflective optical properties that reflect the incoming light and heat (e.g. thermal infrared radiation), thus reducing the heat load on the building interiors. Similarly, it can be made of electricity-producing material, to produce electricity.

In one embodiment, the light transmission is modified by a system that includes two glass layers each having alternate parallel lines of clear (transparent) and high optical density (opaque—the terms “high optical density” and “opaque” are used herein interchangeably) material, and the parallel lines of one layer are oriented parallel to the other layer. One layer may be moved by a small distance over the other layer. When the transparent areas in both layers overlap (as do the high optical density areas) a scene viewed through the pane is clearly visible, while when the high optical density areas in both layers cover the whole area of the glass pane, it becomes very dark. This controls incoming image clarity and light intensity, as well as energy intensity, distribution and amounts.

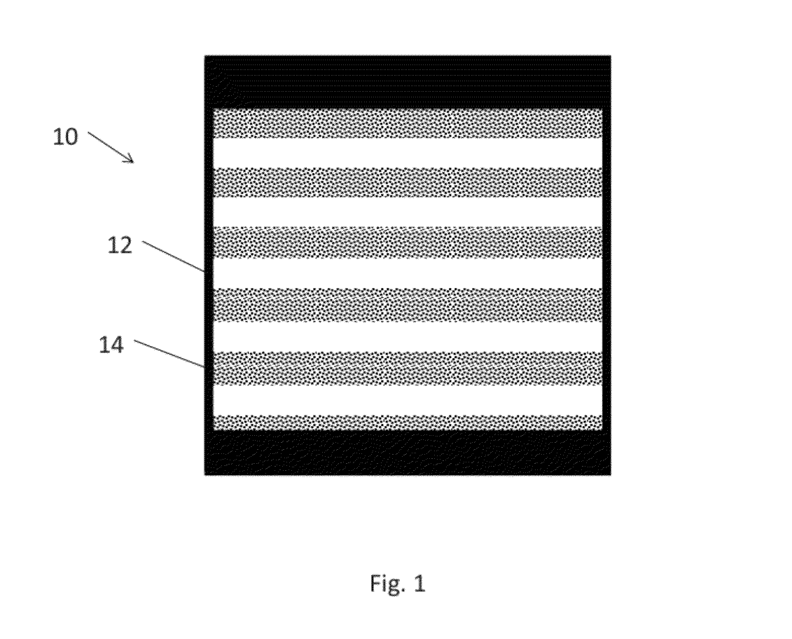

FIG. 1 schematically shows an example of a layer of parallel lines of transparent and translucent areas on a transparent substrate.

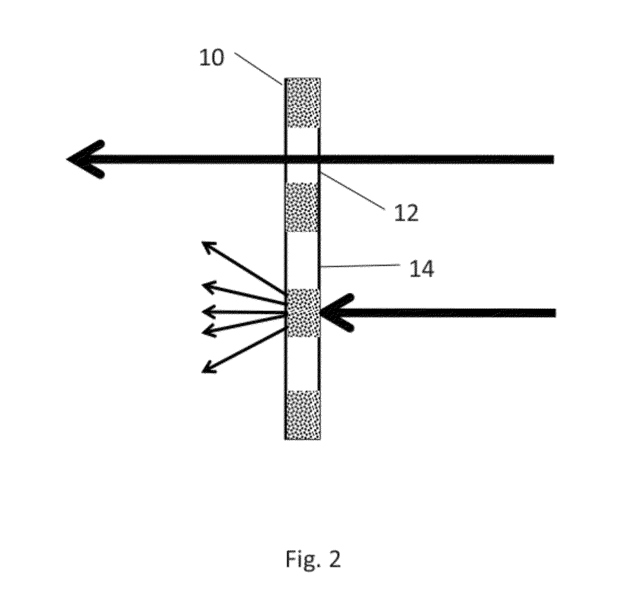

FIG. 2 schematically shows a side view of the layer in FIG. 1.

Embodiments include a system for the modification of light characteristics. Embodiments of the invention include a transparent layer or sheet (such as glass), and an additional light transmitting layer that includes a transparent sheet (such as glass). As shown in FIG. 1, each layer 10 has areas of transparent 12 and translucent 14 media covering most of the area of the panels.

As discussed below, the nontransparent areas may be opaque or may block a significant amount of light. In some embodiments, transparent areas 12 may be more transmissive of light than nontransparent (translucent or opaque) areas, but not necessarily transparent in the sense of a scene being readily viewable in an undistorted manner via the transparent areas.

The transparent sheet may include a transparent medium such as glass that is transparent or semitransparent in the visible light wavelength range, or a synthetic resin sheet that is transparent or semitransparent in a visible light wavelength range. The glass sheet may be made of float glass, soda-lime glass, borosilicate glass, crystallized glass, or the like. The synthetic resin sheet may be made of, for example, PET (polyethylene terephthalate), PVB (polyvinyl butyral), EVA (ethylene-vinyl acetate copolymer), or a cellulose resin. Generally, the transparent sheet may have a thickness ranging preferably from 0.0001 to 30 mm, more preferably from 0.1 to 10 mm. Other dimensions may be used.

The transparent medium can be capable of transferring image-forming light, mainly unaffected in some applications. It should preferably have a visible light transmittance ranging from 10% to 100%, more preferably from 70% to 100%. However, the transparent medium may be, in one embodiment, an add-on medium to the substrate, such as a synthetic resin laminate. The add-on medium may also be gelatin, poly(methyl methacrylate) (e.g. Plexiglas®), or when the overall structure is properly supported; air (e.g., a void). Preferably, the add-on transparent medium has a thickness ranging from 0 mm (absent, a clear empty window) to 10 mm, preferably from 0 to 6 mm (e.g. as compared to standard building glass that is 4 mm thick). The transparent medium can also be any non-transparent, e.g., translucent substrate that was made to be transparent in some of its areas, or was cut out of the translucent medium to make it transparent. Similarly the non-transparent substrate can be optically active substrate, e.g., light polarizing material, a laminate of micro lenses, or lenticular system.

The translucent medium can be, in one embodiment, the substrate of the transparent sheet, which was treated to become translucent, and is capable of scattering the incoming image forming light, so as to scatter and diffuse the image so that it may not be clearly seen by the human eye. It should preferably have a visible light transmittance ranging from 10% to 100%, more preferably from 70% to 100%. Other ranges may be used. The treatment of the transparent sheet into the translucent state can be done by, for example in the case of glass, chemical etching or sand blasting. The translucent medium can also be, e.g., transparent substrate that was made to be translucent in some of its areas.

In one embodiment, the translucent medium may be an add-on medium to the substrate, such as a synthetic resin laminate. Preferably, the add-on transparent medium has a thickness ranging from 0.01 mm to 10 mm, preferably from 0.1 mm to 2 mm. Other dimensions may be used. The add-on medium may also be gelatin, Plexiglas® material, paper, polyester, photographic film, materials added by vacuum deposition, or sputtering techniques, or ink.

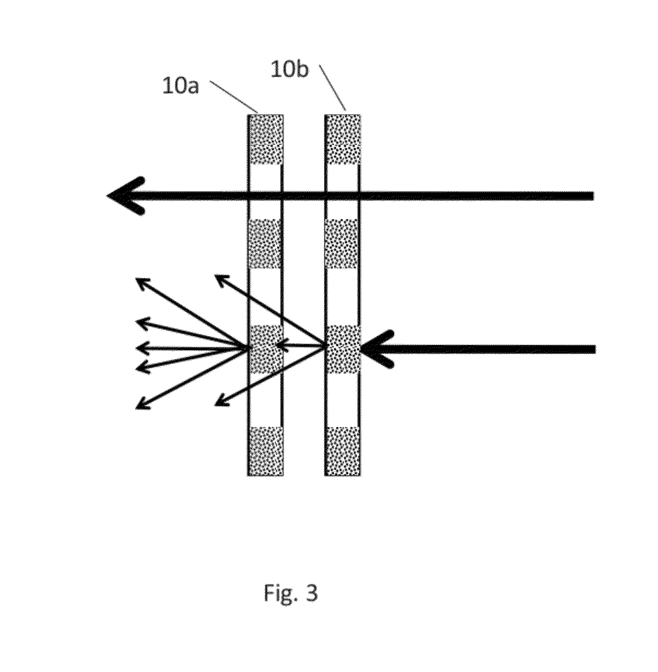

In one embodiment of the invention, the two layers have alternate parallel lines of transparent media 12 and translucent 14 media, respectively, as shown in FIG. 1. Each such layer 10, when observed on its own, may show a clear image through it, as shown in FIG. 2. FIG. 3 schematically shows an illustration of the light passage through two layers producing a clear image.

In some embodiments of the invention, the layers may be substantially identical, with similar patterns of transparent and nontransparent regions. In other embodiments, the patterns on the two layers may differ from one another (e.g. differently sized areas or different spacing between areas). In some embodiments of the invention, the transparent and nontransparent areas in a layer may be substantially identical to one another (e.g. same sized areas with identical spacing). In other embodiments, the transparent and nontransparent areas may differ from one another in size or spacing (e.g. one larger than the other). In some embodiments, the pattern may vary across the area of the layer (e.g. wider nontransparent areas at one end of the layer than at an opposite or other end).

The lines in the layers, in one embodiment, may be equal in width, and may have a width ranging from 0.0001 mm to 30 cm, preferably from 0.01 to 2 mm. Other dimensions may be used. When the two layers 10a and 10b are put over each other, as in FIG. 3, such that the transparent areas of each layer are in phase, e.g., where the transparent areas of one layer are superimposed on the transparent areas of the other layer, and the translucent areas of one layer are superimposed on the translucent areas of the other layer, a clear image of the scenery is seen by the human eye through the overlapping transparent areas. However, when one panel 10b is moved so that its transparent areas 12 are over the translucent areas 14 of other panel 10a, the image becomes less clear.

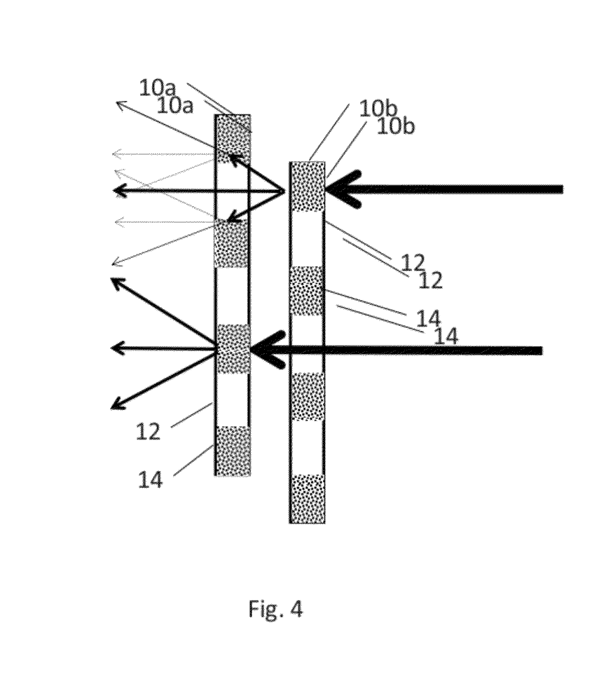

FIG. 4 schematically shows an illustration of the light passage through the out of phase layers producing no clear image.

When panel 10b is moved such that most or all of its transparent areas 12 are over the translucent areas 14 of other panel 10a, all of the light is diffused such that the clear image is replaced by a scattered (diffused) image showing, only very rough, if at all, outline of the observed scene, as is illustrated in FIG. 4.

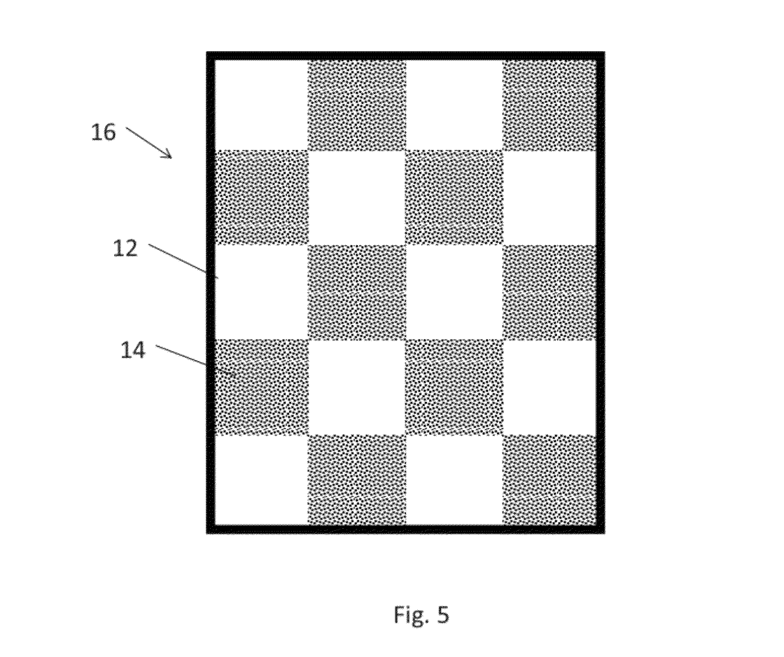

FIG. 5 schematically shows an example of a design pattern of the transparent and translucent areas on a layer.

In another embodiment of the invention, each panel 16 has alternating areas, e.g. squares or other types of parallelograms, of transparent 12 and translucent 14 media, respectively, as shown in FIG. 5. The areas may have a size ranging from 0.000001 mm² to 900 cm², preferably from about 0.0001 mm² to 4 cm². Other dimensions may be used. When two such panels 16 are placed near each other such that the transparent areas 12 of each panel are in phase, e.g. where the transparent areas of one panel are superimposed on the transparent areas of the other panel and the translucent areas of one panel are superimposed on the translucent areas of the other panel, a clear image of the scenery is seen by the human eye. However, when one panel is moved so that its transparent areas are over the translucent areas of the other panel the image becomes less clear. When the panel is moved such that most or all of its transparent areas overlap the translucent areas of the other panel, the clear image is replaced by a scattered (diffused) image showing only very rough outline of the observed scene.

In another embodiment, the system forms a partition within the interior of the building, such as a cubicle in an office. In another embodiment it is used as a partition wall between a conference room and the corridor. In another embodiment it is used as a door. In yet another embodiment it is used as a skylight pane. It can also be very useful as a shop window.

In another embodiment of the invention, the two panels have alternate parallel areas, e.g., squares, of transparent and translucent media, respectively. The areas may have a size for example ranging from 0.000001 mm² to 900 cm², preferably from 0.0001 mm² to 4 cm². Other sizes and shapes may be used. Alternatively, the transparent medium of one panel has a color that is different from the other medium of the same panel. Alternatively, the transparent medium of one panel has a color that is different from the same medium of the other panel and/or the other medium in the other panel. When the two panels are put near each other such that the transparent areas of each panel are in phase, e.g., where the transparent areas of one panel are superimposed on the transparent areas of the other panel, and the translucent areas of one panel are superimposed on the translucent areas of the other panel, a clear image of the scenery is seen by the human eye. This image has a distinct color resulting from the combination of the colors of the various media. However, when one panel is moved so that its transparent areas are over the translucent areas of the other panel the image becomes less clear. When the panel is moved such that most or all of its transparent areas are over the translucent areas of the other panel, the clear image is replaced by a scattered (diffused) image showing only very rough outline of the image, with a distinctive color. In other embodiments, the colors in both of the arrays above are the same. Similarly, an arrangement of colored or clear transparent and nontransparent areas on one or both panels may be configured to create a pattern when passes through the patterns. The pattern may be changed by relative movement of the panels. This method and system may also be applicable to filtering out undesirable sections of the electromagnetic spectrum, such as heat.

The movement of the layers against each other can take many forms. In one embodiment one layer is stationary and the other layer is moving back and forth parallel (or substantially parallel) to the stationary layer.

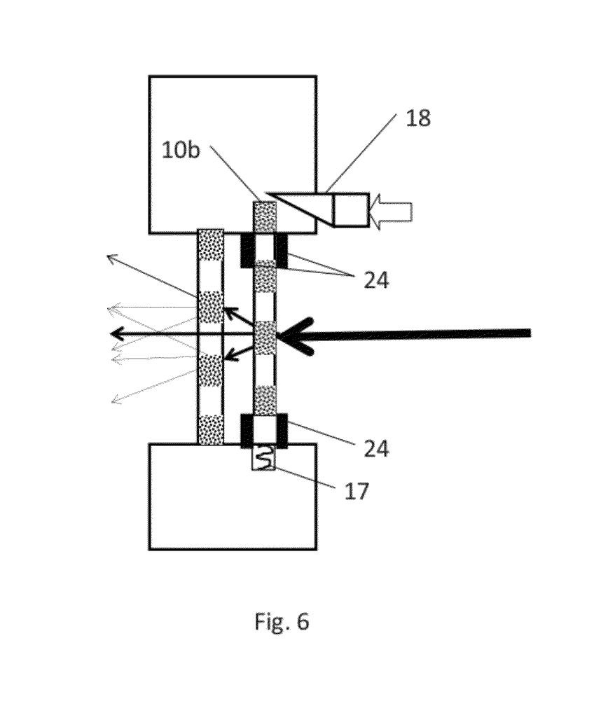

FIG. 6 schematically shows an example of a mechanical activation mechanism, using a wedge, when the layer is moved to an out of phase position.

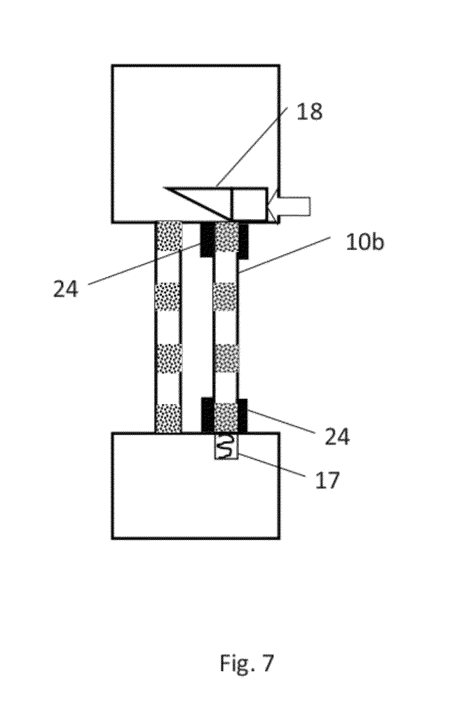

FIG. 7 schematically shows an example of a mechanical activation mechanism, using a wedge, when the layer is in an in-phase position.

The movement can be generated by a button 18 in the shape of a wedge that is lodged against the moving layer 10b, and when pressed the wedge 18 is pushing the layer in the direction of the slope of the wedge, as shown in FIG. 6 and FIG. 7. When released, moving layer 10b may be returned to its original position by spring 17. As the required distance for movement of moving layer 10b is usually not more than 2 mm, such method may be advantageous.

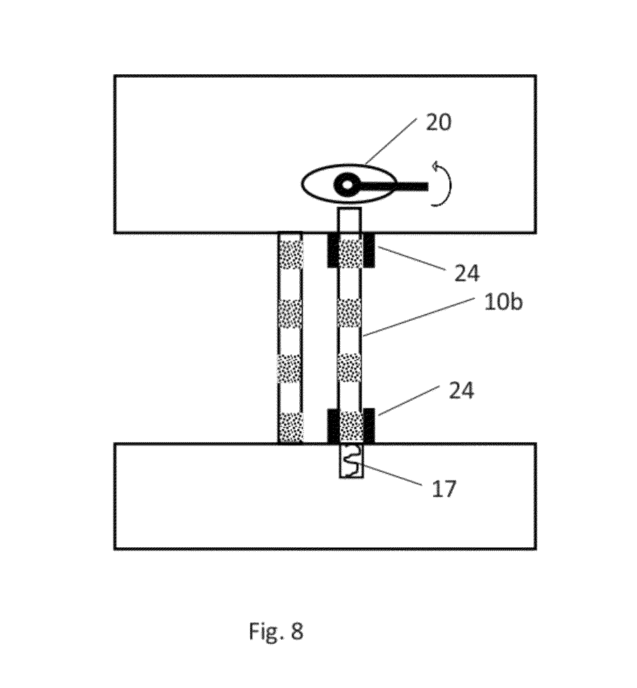

FIG. 8 schematically shows an example of a mechanical activation mechanism, using an elliptical dial, when the layer is moved to an out of phase position.

In another embodiment the back-and-forth movement is facilitated by an elliptical dial 20, as shown in FIG. 8. In another embodiment of the invention, an eccentrically mounted disk may be used in place of the elliptical dial. In yet another embodiment the move is created by a screw that is connected to a dial or a button. When turned the screw moves one layer over the other. This method may be advantageous when intermediate stages of the layers superposition are required.

In another embodiment the movement of one layer over another layer can be generated by an electromagnet, or a solenoid system, that pushes one layer over the other by the predetermine distance when activated, e.g. by a switch or button.

When the layer or layers move horizontally, a mechanism to reduce friction can be used to ease the motion such as a polytetrafluoroethylene (e.g. Teflon® material) truck or micro-wheel system. Also, guiding tracks 24 may be used to guide the moving layer in the desired direction and for accurate positioning versus the other layer or layers. When the layer or layers move vertically up, the motion may be assisted by a spring 17 at the bottom, which would counter the weight of the moving layer, as shown in FIGS. 6-9. Such spring counterforce can also be used in other directions of motion.

A piezoelectric system may be used to move one layer over (or along) the other layer.

A system using translucent areas has the capacity to display images projected on it. This capacity is inherent in a system that has translucent areas in it, while this capacity is enhanced when the translucent area is increasing in size as a result of the movement of the layers when more translucent areas are superimposed on the transparent areas, exposing both translucent areas to the projected image. For example, an image may be back projected onto a window, partition, or similar structure of an office or conference room when the window is in a translucent configuration.

A similar system may be employed with a shop or gallery window. The system is very versatile in that it provides the options for the window to be transparent, or translucent, providing privacy and enabling an image to be projected (back or front projection) on it. This ability to display projected images can also be used for advertising. The system also has the ability to accept and display projected images while in the transparent mode (on the translucent regions of the window). In this case, customers can view the content of the shop window but also are exposed to the projected advertising that is superimposed on the scene, providing a convenient and cost effective means for the shop owner to advertise.

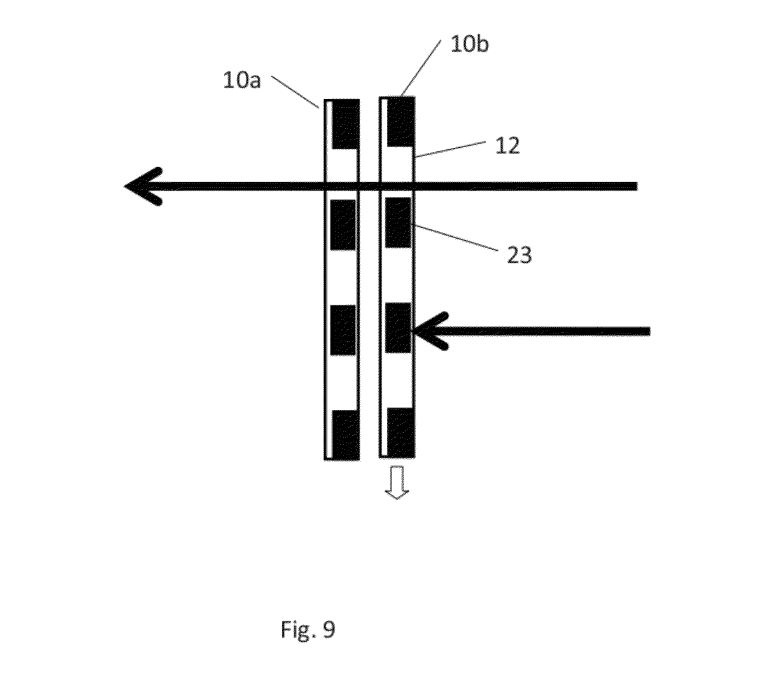

In another embodiment, the system is as described above, where the translucent lines or areas are replaced by opaque or high optical density material (where optical density of an object is defined as the negative of the logarithm of the transmission of the object). FIG. 9 schematically shows an example of side view of the two layers side by side with areas of high optical density material, with their transparent and dark areas superimposed.

The high optical density material can be ink, laminate, pigment, or paint of any kind. When the layers 10a and 10b are superimposed in phase, such as in FIG. 9, and the opaque areas 23 are assumed (or are made) to be completely opaque, the total light transmission of the window pane is about 50% because opaque areas 23 occupy 50% of the window pane, and the remaining 50% corresponding to transparent areas 12 is assumed to transmit close to 100% of the light shining on it. However, when moveable layer 10b is moved over stationary layer 10a, so that opaque areas 23 cover the transparent areas 12 (or lines), a gradual decrease in light transmission occurs. When the opaque areas 23 completely overlap transparent areas 12, the overall transmission of light by the window is reduced to a minimum, which is equal to the transmission of opaque area 23 in one layer 10a or 10b. The opaque area 23 may be in fact of any optical density, which provides a lot of permutations for the transmission of light by the system.

For example, a very light (low optical density) shading may be provided by one layer having its optically dense areas 23 at an optical density of 0.1 and the other layer having its optically dense areas 23 set for an optical density of 0.2. When superimposed, in this example, the optically dense areas have density of 0.3 or 50% transmission of the light, while the transparent areas 12 pass close to 100%, and the average is about 75% on the whole area of the window pane. When the layers are moved and the dense areas are over the neighboring transparent ones, 50% of the window pane area has a density of 0.1, meaning approximately 80% of the light is transmitted, while in the other 50% of the area, the density is 0.2 or only 63% of the light is transmitted. The average transmission of the window pane then is about 71% of the incident (coming) light. In this case the system provides a control of light transmission between about 71% and 75%. If, for example, the areas have different colors, moving a layer relative to the other may introduce relatively subtle room lighting effects or visible patterns in the window pane.

However, if in one layer the optically dense areas have an optical density of 0.3 (which means that they transmit 50% of the light) and in the other layer the optically dense area have optical density of 0.7, then the window pane transmission in the superimposed mode (optically dense on optically dense and transparent on transparent) of the combined dense areas is 1.0, or light transmission of about 10%. As the transmission in the clear superimposed areas is close to 100%, the average appearance of the whole window is about 55%. However, when the layers do not superimpose on each other, but on their neighboring ones, the optical density may be 0.7 and 0.3, respectively, creating transmissions of approx. 20% and 50% in each area, to create an overall visual impression equivalent to a transmission of about 35%, and the control over light transmission of the system is between 35% and 55%. The maximum range, using only two layers is when the high density layer is of very high value >3.0, and the range is then from <0.1% to 50%. In another embodiment, the high optical density areas of each layer may not have the same optical density throughout the entire window pane. In one example, the high optical density areas may have a lower optical density near the top of the window and higher optical density near the bottom. This may allow for higher transmission of light at the top of the window (for example, in order to get more sunlight), and lower transmission of the lower window area for increased privacy. Such effect can also be achieved by having window pane where the layers nontransparent material in the top part of the window include optically dense material to shade from the sun, and translucent material in the bottom part of the window to enable privacy from the street level scene.

The transparent area in the system may also include some optically dense material to decrease its transmission, and it can include color to make it colorful.

It may also incorporate materials that filter various sections (e.g. infrared) of the spectrum to cut out light and heat.

It may also include (e.g. photovoltaic) materials that can produce electricity, having conducting material for connecting the electricity-producing material at the center of the glass pane to its sides.

In another embodiment the dense areas and/or the transparent areas are spectrally selectively transmissive, tinted with various colors. This result in a change in color appearance of the window when the layers are moved, creating many possibilities of colored windows permutations.

Similarly, patterns may be incorporated into the layers in such a way to be viewed on the window when the changes in light characteristics occur. For example, when a particular optically dense area is colored in green and another optically dense area colored in red, when the optically dense areas superimpose the window appearance in that section may be very dark, while the transparent areas are bright and neutral in color. However, when the optically dense colorful areas move over the transparent areas, the whole window may have red and green areas in close proximity, which appears to the eye as yellow.

A high density material may absorb solar radiation and become hotter. Double glazing may reduce heat transfer from the high density material to the interior. However, use of reflecting material may prevent the high density material from heating, thus eliminating or reducing a need to use double glazing to reduce the heat transfer. The high optical density areas can also be suitable to reflect heat energy, with reflection in the far, or thermal, infrared (IR) spectrum. When such heat reflecting material is used, it may be very suitable for heat load reduction in a building when the layers are placed in exterior window and door panes in a building, or in skylights. To further reduce the heat load, the layers can be placed within a double glazing window system, where vacuum, or the appropriate medium, insulate the building interior from heat absorbed by the heat absorbing layers in the pane. The transparent or nontransparent areas may be spectrally selectively transmissive. For example, the areas may transmit infrared or visible radiation while absorbing, scattering, or reflecting radiation of another spectral region.

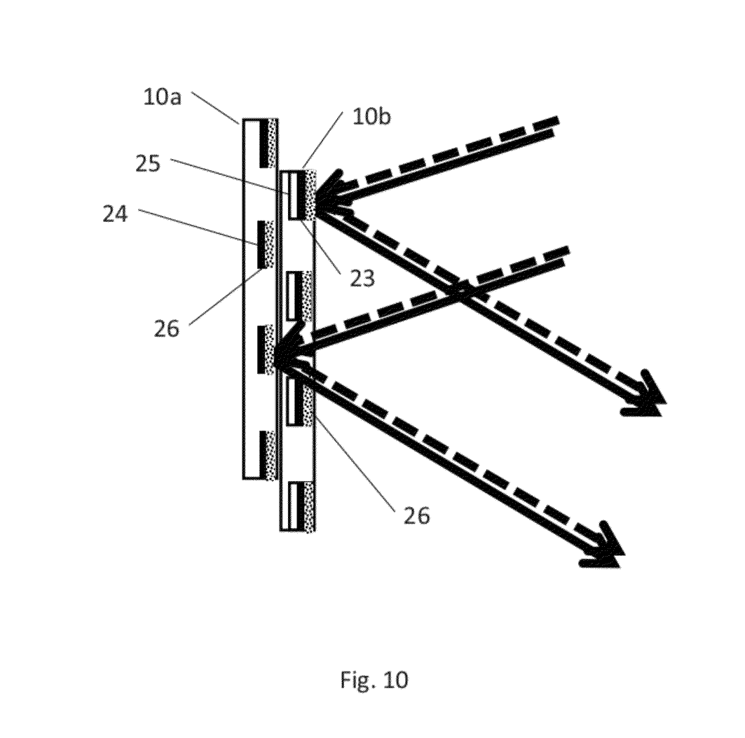

FIG. 10 schematically shows the two layers, where the high optical density (opaque) areas cover the transparent areas such that no light (or reduced intensity light) is passing through, with the external side of the opaque material including heat reflectors.

The high optical density areas 23 can also be made, or coated, with reflective material 26 on the outside (of the building) side of the layer 10a or 10b, thus at least partially reflecting incident light and heat radiation, and hence reducing the heat load on the building interiors. An interior side of high optical density areas 23 may include interior coating 25. For example, interior coating 25 may include a desired color (e.g. room or wall color). The separate layers may be combined into a single layer (e.g. colored reflecting material as an opaque material).

Similarly, the diffusing material for the translucent system may incorporate heat reflecting materials that will reduce the heat load on the building interiors. An additional layer of heat reflecting may be transparent, or semitransparent, or a selective mirror, that may reflect the heat while allowing the light to pass on to the translucent layer behind.

Similarly, the transparent areas may be coated with a material that is partially reflecting to at least some (e.g. a given spectral region) incident radiation.

The layer or window paned may be reversible. For example, during summer, the reflective layer may face the outside such that incoming solar or other radiation is reflected out of the building. In winter, the window, or a layer of the window, may be reversed such that the reflective layer faces inward. This may enable interior heat to be reflected back into the building, while incident externally (e.g. solar) radiation may be absorbed. Thus, the window may assist in heating the building interior during a cold season, and protecting it from the heat and reducing the heat load during a hot season.

In some embodiments, the various layers are identical or similar to one another. In other embodiments, the layers may be different. For example, one or more layers may include translucent nontransparent areas, while another layer includes opaque areas in place of the translucent areas.

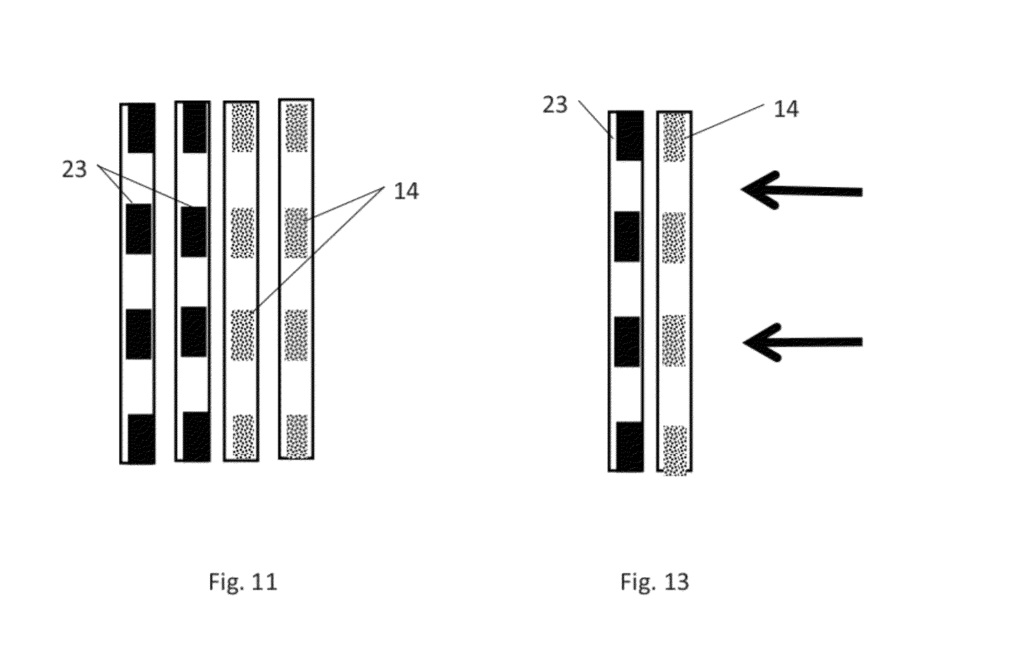

In another embodiment, the combined invention of the “transparent to translucent” and of the “transparent to opaque” modes is made. FIG. 11 schematically shows a combined system of four layers containing transparent, translucent, and opaque areas.

In one form, four layers (two layers of opaque and two of translucent materials) are combined, and the layers are placed side by side near each other. Where all the layers are in phase, as shown in FIG. 11, light passes through the transparent areas creating an image by the human eye. However, if either the translucent or the high optical density areas in the other layers are moving over the transparent areas, the desired effect of losing the image is achieved as described before. This system provides the flexibility to have transparent to translucent and transparent to opaque in the same window (or system).

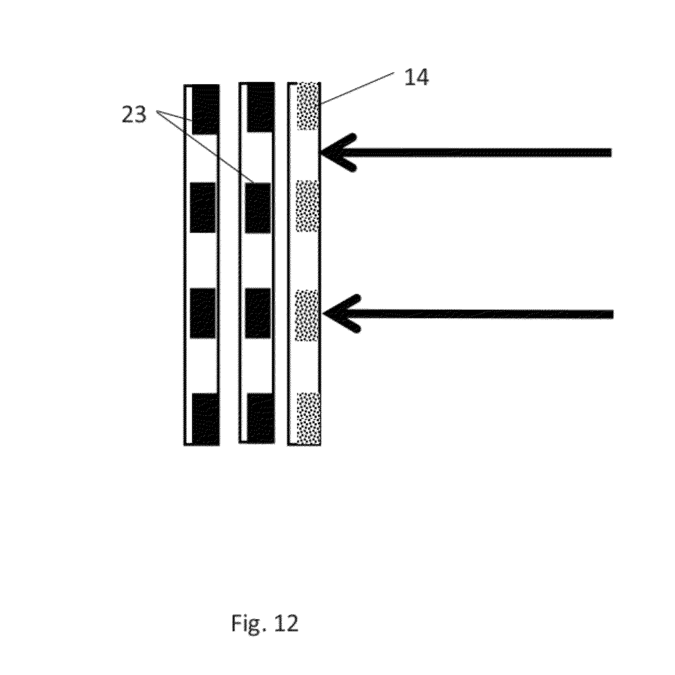

FIG. 12 schematically shows an example of the use of three pane layers within a window. Another embodiment for combining the various modes discussed above is to use only three layers. The transparent areas are common for all three layers, and moving only the two layers, for example the high optical density one and/or the translucent one may provide the desired effect. This system may have some reduction in light intensity because the high optical density areas are always present to reduce the incoming illumination; however, there may be a choice of gaining privacy in two ways, either with constant illumination, by moving the translucent layer, or by reducing incoming and outgoing light intensity, by moving the high optical layer.

FIG. 13 schematically shows combined system of two layers containing transparent, translucent, and opaque areas according to an embodiment of the invention. In another embodiment, the high optical density layer can be part of the stationary windowpane, and the only layers that move are the other layers, the one with the high optical density material and the layer with the translucent material, respectively. Thus with only two moving layers the system provides the option to have either translucency or further reduction in illumination. This configuration also has the option of not using the third, immovable layer, such as the stationary windowpane as discussed above, in using only two moveable layers. In this case, moving the translucent areas layer over the clear areas of the high optical density layer may not allow an image to be formed through the window, but may maintain the luminance level inside the room.

In another configuration, only two layers are considered, out of which only one may be moved. Using the two layers: the one with the high optical density material, in this example, may be immovable, and the translucent material layer may be movable. When the translucent areas overlap the high optical density areas a clear image is viewed, due to the transparent areas that are free to pass the light, however, with reduced light intensity which is caused by the high optical density areas occupying 50% of the total window areas. When the translucent layer moves and the translucent areas are over the transparent areas of the other (high optical density) layer, the low intensity image is scattered away by the translucent material, providing privacy at lower incoming light intensity. Another advantage of this system over the system in which only translucent material is used is that visible haze or blurriness, which may be created by the superimposed translucent areas (in the “clear mode”) may be reduced (e.g. to zero), due to the opaque layer stopping the scattered light of the translucent material from reaching the eye.

In another embodiment, the lines width, or the area width, of the high optical density layers may not be the same as the width of the transparent lines or areas. Making the high optical density lines, for example, narrower, would allow higher transmission of light in both superimposed, in phase, mode and in overlay, or out of phase, mode. This may be useful in the case where total opacity, or no light transmission at all is not necessary, however, higher transmission in the “bright” mode is sought. This may be the case of eye glasses, where total opacity is not required, but maximum transmission may benefit low light environment (evenings and nights). Also, variable width, or area, of the nontransparent material can be used within the same panel, thus allowing variable (and gradual) shading with the movement of the panel. For example: having thinner lines at the bottom of the panel compared to the top, may allow lower transmission of the top of the window than the bottom. Thus the window may mask or shade the sun effectively when the sun is high in the sky, while allowing unobstructed viewing of the street below.

When a combination window is possible, the window can be made to turn from clear image transmission to either translucent or opaque and a combination thereof. In one example, the system may combine in one pane the transparent and translucent areas and in another pane the transparent and opaque areas. This may allow for a system whereby in one mode, when the clear areas are maximally exposed, the window is dim, with 50% light transmission due to the high optical density area in the other layers of the pane, however, with a clear image. In another mode, where the translucent areas are moved over the clear areas the window is dim but with only scattered light and no clear image.

In another example, the system may combine transparent and translucent areas in a single pane, while the other panes may be of transparent and opaque areas. This may allow for a system whereby in one mode, where the clear areas are showing at the maximum, the window is dim, with 50% light transmission due to the high optical density area in the other layers or panes, however, with clear image. In another mode, where the translucent areas are moved over the clear areas the window is dim but with only scattered light and no clear image. In yet another mode, the high optical density areas are moved over the clear areas to cut off all the light transmission, creating no light and no image. All the intermediate stages in the above examples are also possible, for example, less light passing through, say only 20% transmission, but the light being scatted for privacy.

To increase the area that is passing unaffected light through the window (panes), a system of multiple moving panes can be used. For example: two moving windows panes and one stationary pane may have, for example, lines of 1 mm wide high optical density material and gaps of 2 mm between the lines. When the three layers are superimposed, only ⅓ of the glass area is blocked, while ⅔ is clear. Similarly, if translucent material of any other optically affecting material is used. The more layers that are used, the larger the (unaffected) clear area of the window when the layers are superimposed on the optically affecting areas.

A system may have multiple panes of which some are movable. The multiple panes have areas that are clear and areas of high optical density material. Moving the moveable panes can render larger areas of the window opaque when they are complementing each other's dense areas than when they superimpose their dense areas over each other.

A system may have multiple panes of which some are movable. The multiple panes have areas of clear and translucent material. The moving the moveable panes can render larger areas of the window translucent when they are complementing each other's translucent areas than when they superimpose their translucent areas over each other.

A system may have multiple panes of which some are movable. The multiple panes have areas of various optical properties. The moving panes can render larger areas of the window of some optical property when they are complementing each other's areas with the optical property than when they superimpose their particular optical properties areas over each other.

These multiple panes system may also be used to offer the user the choice of obtaining reduction in light intensity or increase in light scatter. For example, one stationary pane may be used with two moving panes. All may have similar patterns of optically light modifying areas, for example, one with high optical density areas and the other with translucent scattering material areas. The user is given a choice of moving either the high optical density or the translucent areas moving panes. When the moving pane with high optical density area is moved over the clear area of the stationary pane the light intensity in the room is reduced. On the other hand, when the translucent areas moving pane is moved over the clear areas of the stationary pane the image becomes scattered until it is not seen, providing privacy.

Using multiple layers, when each layer has relatively high thickness (e.g., >0.2 mm), may enable a possibility where unaffected light may penetrate at an oblique angle to the stationary glass pane. To reduce this effect the moving pane may have the optically modifying areas (for example: translucent or high optical density areas) deposited in both sides of the pane.

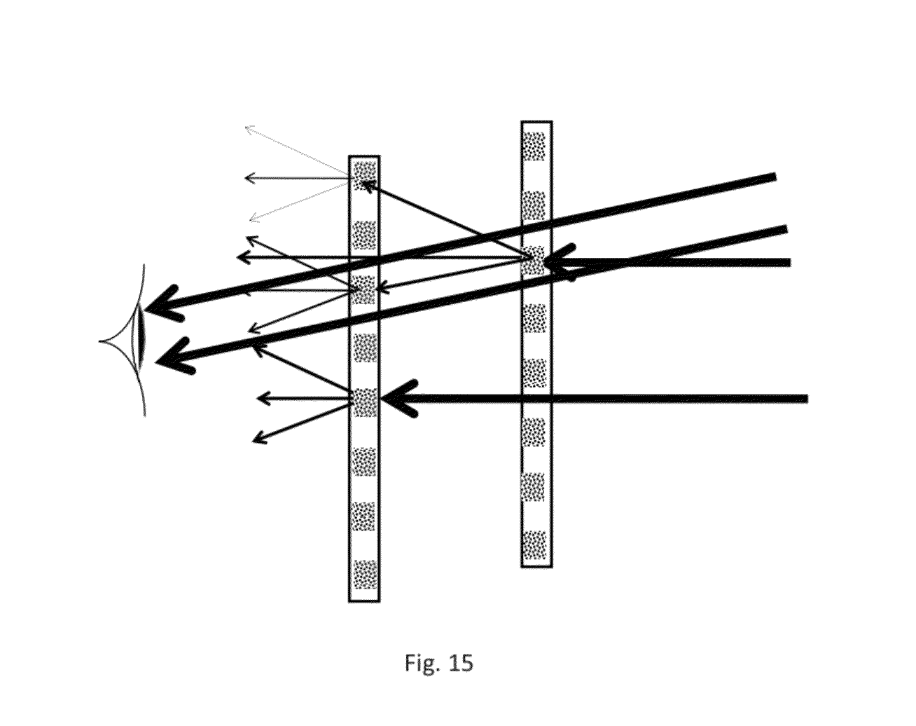

FIG. 15 schematically shows an example of a wide gap between the layers that causes a partial image to be seen when the system is in a translucent mode according to an embodiment of the invention. The distance between the layers may determine the angle of the oblique angle of unaffected light penetration, and accordingly, which part of the scene can be viewed via the window. The distance between the panels can be designed to block, for example, the central section of the image coming through the window system, providing selective privacy dependent on the scene to be viewed. Attempt to view the blocked area by moving the eye up of down will fail, as the blocked area moves together with the moving eye. For example, if used in an office partition to a conference room, a partition made of transparent and translucent materials with an appropriately designed line width and distance between the panels, may allow an outside observer (from the corridor) to see part of the floor and ceiling of the room, but not the central part of the image (e.g. the faces of participants in a meeting). Moving up or down would still not allow the observer to view the central part of the image.

A multi-layer system may also be made using layers of different material and thicknesses such as glass, Plexiglas® material, polyester films, photographic films, polyester film (e.g. Mylar® material), or polycarbonates. This may allow for less weight and thickness of the layer than if the layer were made of glass.

The discussion above illustrates that large areas within (or on) the (glass) panes may be used to allow for the system to become opaque or translucent. These areas, which are either opaque or translucent, can be used for the generations of electricity.

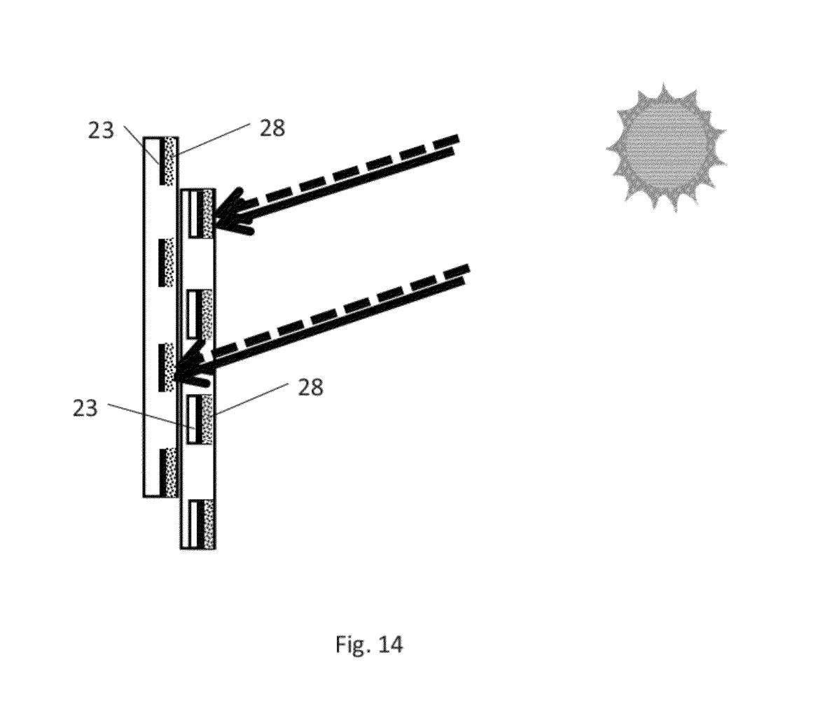

For example: the areas 24 of high optical density that are used to reduce the light intensity, are deliberately made of high optical density, or high opacity, material so that they have high light stopping power. This means that these high-density areas are designed not to transmit light and any addition of non-transmitting light material may not change the window light characteristics in adverse way. FIG. 14 schematically shows photovoltaic material coated on the high optical density areas of the layers.

Hence, material that produces electricity 28 can be added to the high-density areas without affecting the light characteristics of the window as compared to adding high-density material alone. Also, the material that produces electricity may be (or can be designed to be) of sufficient opacity to also serve as a high-density material for absorbing light and heat.

Thus, in accordance with embodiments of the present invention, when the minimum transmission of light is desired and the high-density layers of the opaque system are out of phase, with photovoltaic (PV) cells attached, maximum window area is available for electricity generation.

Accordingly, the window may have a different appearance in the exterior and the interior sides. At the exterior, the window may have the appearance of the PV cells on a dark background, while on the interior side the window may look black or any other color.

Due to their thin nature, some of the PV materials are semi-transparent, and some may scatter light. Accordingly, they are also suitable for incorporation into a translucent layer in accordance with an embodiment of the invention.

The PV material that can be of cadmium telluride (CdTe), copper indium gallium selenide (CIGS), dye sensitized, or organic materials, and may be chosen based on considerations such as cost and efficiency.

The high optical density areas (as well as the translucent areas) can be arranged as parallel lines that can be made of conductive material with transparent (or partially transparent) area between them made of p+, p, n+, p+, p, or n+ material. Thus, the electricity generating structure may be intrinsic to the window pane.

In another embodiment, the movement of one layer over the other is facilitated by magnets that transfer the force required for the movement through a double glazing glass; thus preserving the insulation and environment of the inner volume of the double glazing system.

The examples provided above assume the layers are flat, straight or plane. However, in other embodiments, such as in sunglasses, crash helmets, or car windows, the layers can be curved, arched, or wavy.

It is usually advantageous to place the layers adjacent to each other with minimum distance between them. This distance is usually guided by the guiding tracks that the system uses. An increase in the distance between the layers may cause a change in the resulting optical effect. For example, in the completely translucent mode, when no clear image is seen or desired, a large distance (of few millimeters to a few centimeters) may cause a clear image to be observed by the human eye. This may happen in certain angles that have high deviation from the perpendicular angle to the system. FIG. 15 schematically shows an example of a wide gap between the layers that causes a partial image to be seen when the system is in a translucent mode.

However, in another embodiment, when such effect is desired, for example, in an internal partition in an office, where the system using, for example, alternating transparent and translucent lines of 5 cm, a 2 cm gap between the layers, in the maximum translucent mode, may allow the possibility to “peek” and see if there is anybody (e.g., a receptionist) on duty.

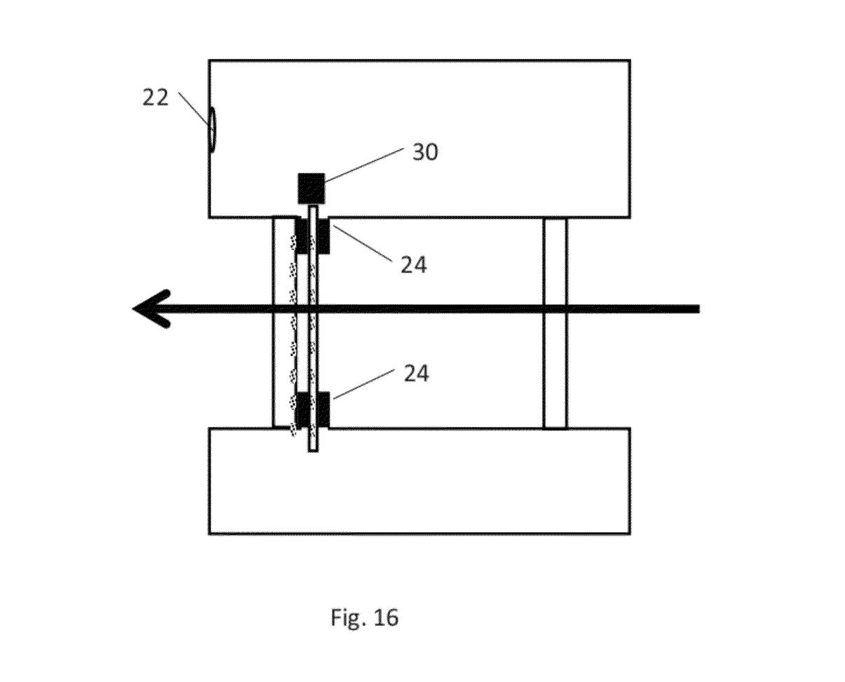

The system can be positioned in various ways. FIG. 16 schematically shows an example of a design of a standard double glazing window, modified to add a layer of transparent and translucent areas, and an additional layer of transparent and translucent areas, where the two layers are in phase.

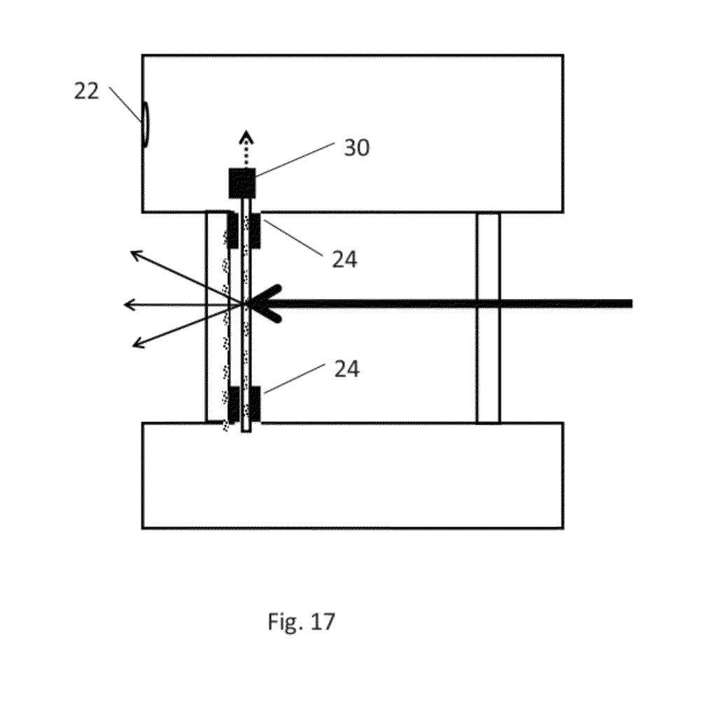

FIG. 17 schematically shows an example of a design of a standard double glazing window, modified to add a layer of transparent and translucent areas, and an additional layer of transparent and translucent areas, where the two layers are out of phase.

In one embodiment, a layer with transparent and nontransparent regions may be positioned within a double glazed window, as shown in FIGS. 16 and 17. Included is a moving mechanism (for example, including piezoelectric motor 30), and guides 24 for guiding and holding the layer.

The moving mechanism to move one layer, over another layer can include various mechanical and electrical devices. For example: a simple wedge shaped button, where the increased pressure on the button drives the wedge between the pane and the window frame, thus moving it with the increased thickness of the penetrating wedge. An electrical motor can be used to move the pane as well as any system that is placed between the pane and the window frame and is made to expand, thus pushing the pane.

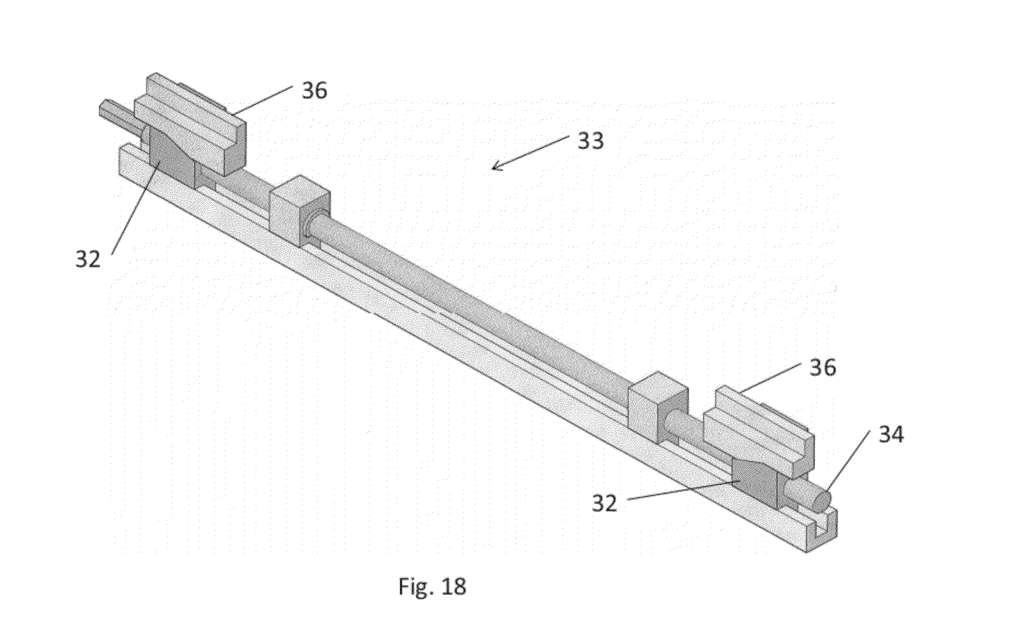

FIG. 18 schematically shows a moving mechanism for a layer.

A moving mechanism 33 can be based on a reverse screw shaft, which has moving parts 32 that move in opposite directions when the shaft 34 is rotated. These moving parts 32 have slope in their interior side, which is similar to the slope of a part 36 attached to the moving glass panel, which is also in contact with them. When shaft 34 is rotated, the moving parts 32 attached to it are moving in opposite directions forcing the matching sloped parts 36 attached to the glass to move up or down, depending on the direction of the turn of the shaft. Additional moving parts, pairs, similar to 32 can be added, for multi panel system to move several moving panels. For example: additional pair of part 32 and 36, on the same shaft 34 with different slopes (say, higher slope), and extended depth (to accommodate the second glass behind the first (e.g. an extra 4 mm on average), may move an additional panel at higher speed and longer distance than the other (original) panel, reaching its final destination at the same time as the original panel.

The shaft 34 for moving the glass can be rotated manually, using a dial type knob, or by mechanical or electrical motor. Such motor can be remotely controlled using remote control electronic unit which uses infrared or radio wave communication.

The activation of the system can be made by the user, manually or by using a remote control, or by heat or light sensors activating the associated motor that moves the panes.

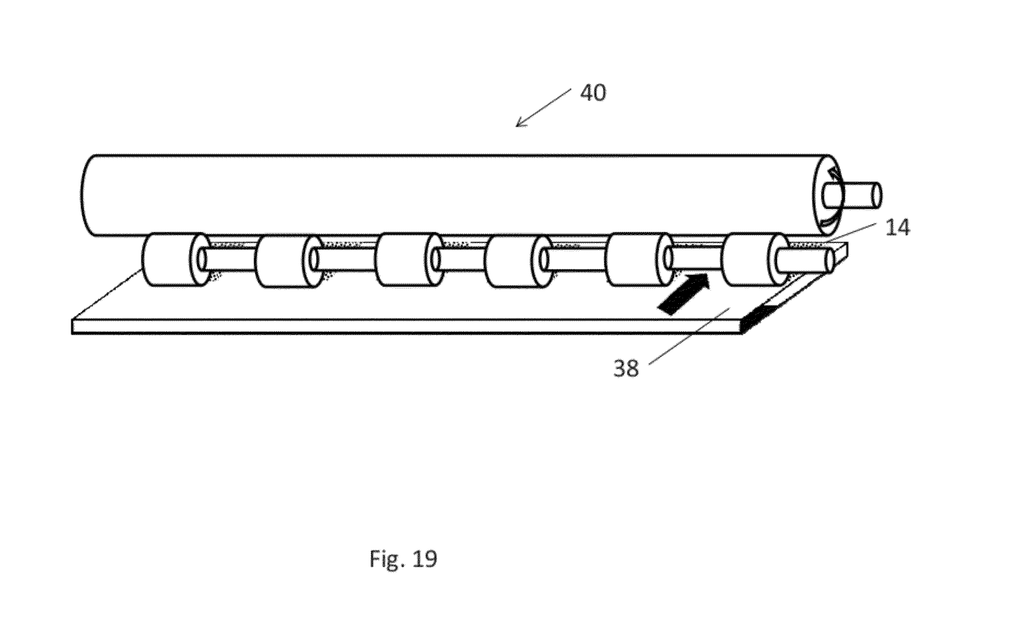

The advantages of the system may include low production costs. FIG. 19 schematically shows an example of producing a translucent layer of translucent ink on a transparent substrate using flexographic printing.

In one embodiment, the translucent lines 14 are printed by a flexographic printer 40 on the transparent substrate 38 as shown in FIG. 19. The flexographic printing or other offset printing may provide a convenient, efficient, and low cost production means to implement embodiments of the invention.

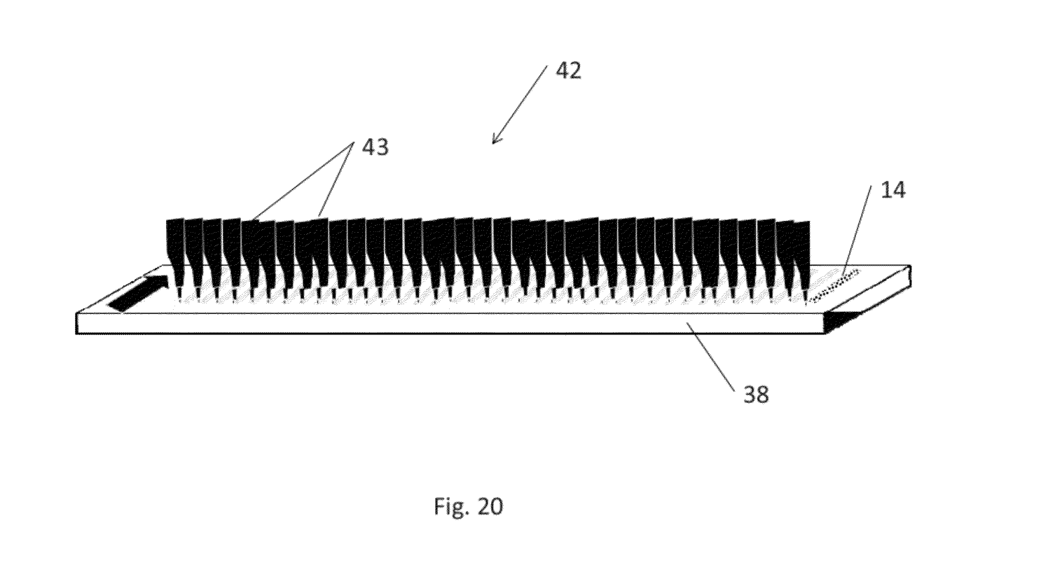

FIG. 20 schematically shows an example of producing a translucent layer of translucent ink on a transparent substrate using inkjet printing.

In the illustrated embodiment, when very thin translucent lines 14 are desired (in the microns level) an inkjet printing mechanism can be deployed. The inkjet printing heads 43 can move as customary, or, to increase productivity, can be arranged in a row 42 oriented perpendicular to the movement of the transparent substrate.

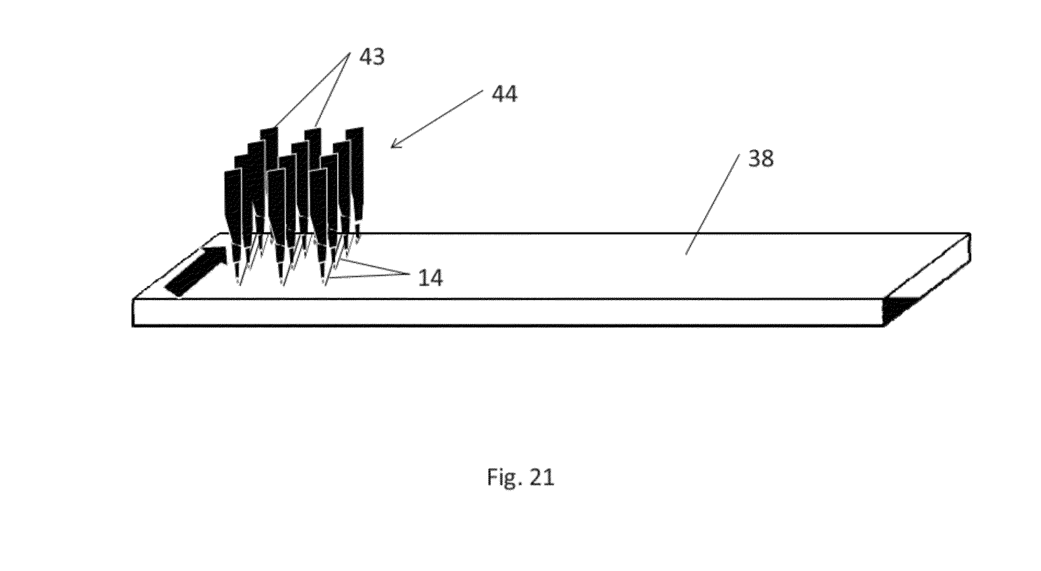

FIG. 21 schematically shows an example of producing a translucent layer of translucent ink on a transparent substrate using inkjet printing, where the printing heads are also aligned behind each other to allow for narrower gap between the lines. In an embodiment, when a very high optical density of lines is required, which may be higher than the inkjet head positioning may allow, a cascading arrangement 44 of inkjet heads 43 may be used. The inkjet heads are placed in cascading perpendicular rows, behind each of the printing heads 43, each inkjet printing head 43 printing a very short distance away from the previous line, which was generated by the inkjet in front of it. This may increase the resolution, or the number of lines printed.

Other methods may be used to deposit a material on a transparent material or substrate so as to form a nontransparent area. Such methods may include, for example, sputtering and vacuum deposition (e.g. of a metal or metallic compound). Such a method may be controlled so as to deposit a predetermined thickness of material on the substrate.

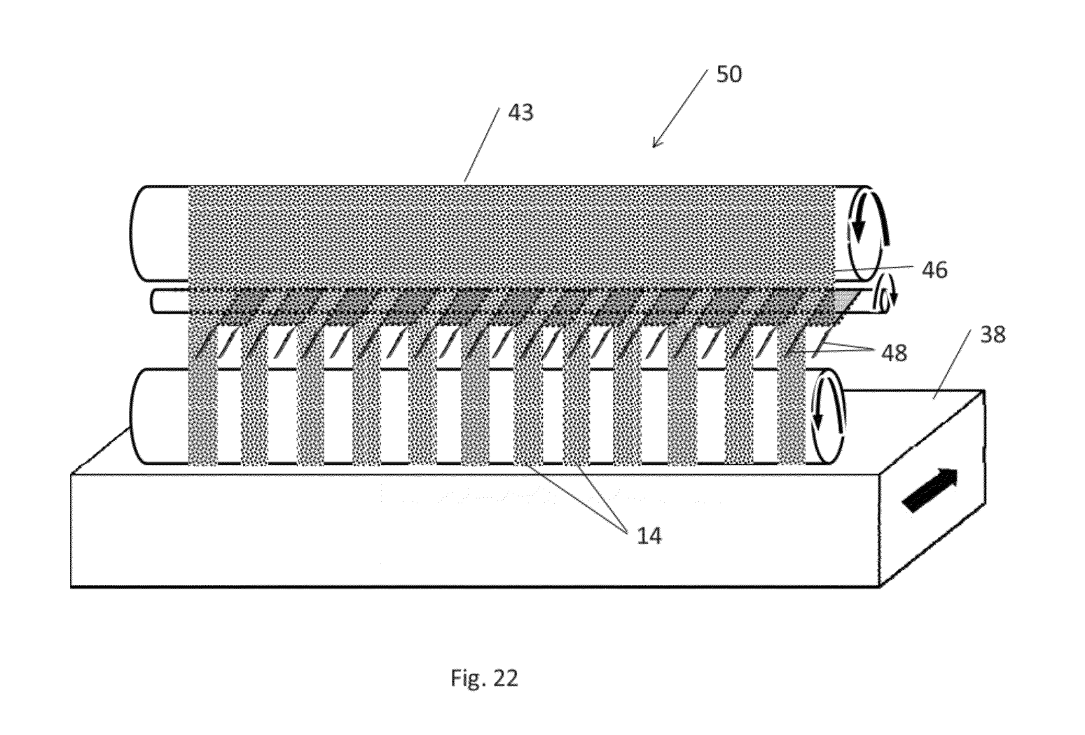

FIG. 22 shows printing (depositing) laminated optically modifying material on a transparent pane. Another method to deposit optically modifying areas on the panel is by pressing a laminate 46 or polymer material of the required optical properties onto the panel 38 using lamination device 50. Coated strips of laminate 46 may be separated from uncoated strips using a series of blades 52.

To avoid dirt, humidity condensation, and insects from entering the gap between the (glass) panes, the panes can be enclosed in a sealed environment.

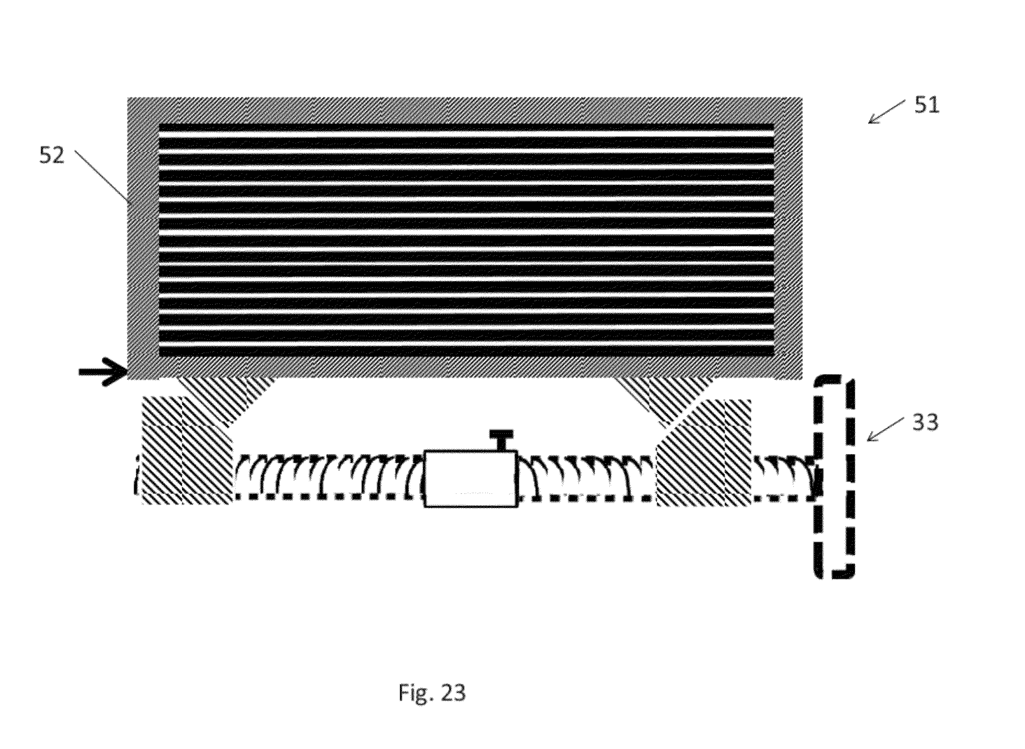

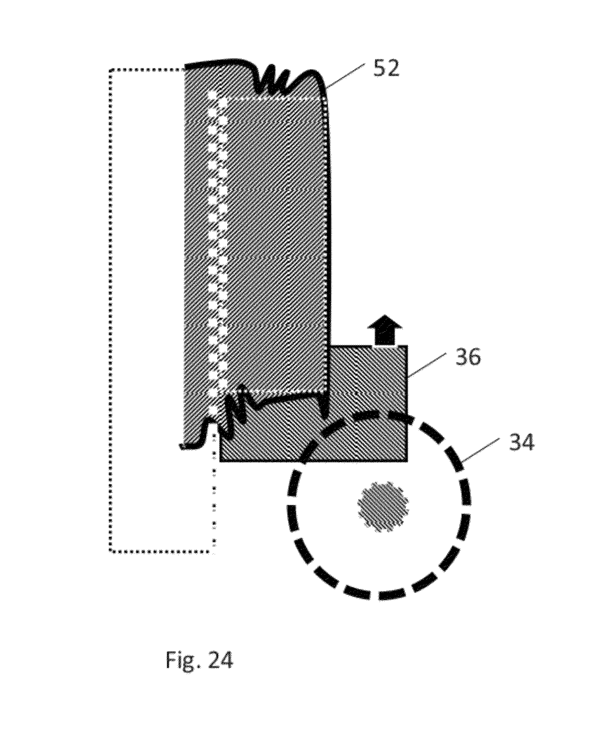

FIG. 23 shows a front view of an insulating layer between the stationary and the moving layers to avoid dirt and obstacles from getting into the space between the glass layers. FIG. 24 shows a side view of the insulating layer shown in FIG. 23.

Such a sealed environment can be a double glazing unit described above, or a seal 52 made especially for this application. Such a seal 52 can be made of an elastic membrane, such as latex, which is connected to the stationary pane, for example by glue, and to the moving pane. Seal 52 may include such sealing materials as, for example, rubber, latex, resin, silicone, polymer, or nylon. The sealing material may include any other material that may be capable of providing suitable protection against the element and being flexible enough to absorb small movements of the glass that may be as small as 0.01 mm. Such membrane may cover the gap between the panes from the outside, as shown in FIG. 24 and FIG. 23. The short distance movement of one pane over another, for example, half a millimeter, could be accommodated by the membrane.

In accordance with an embodiment of the invention, a non-transparent area of a layer or panel may include a system of cylindrical (linearly symmetric) or ordinary (axially symmetric) lenses, micro-lenses, or a lenticular structure. The focal length of the lenses may be short enough that when a viewer is standing at a distance from the window that is greater than the focal length, the effect is similar to a scattering (translucent) medium.

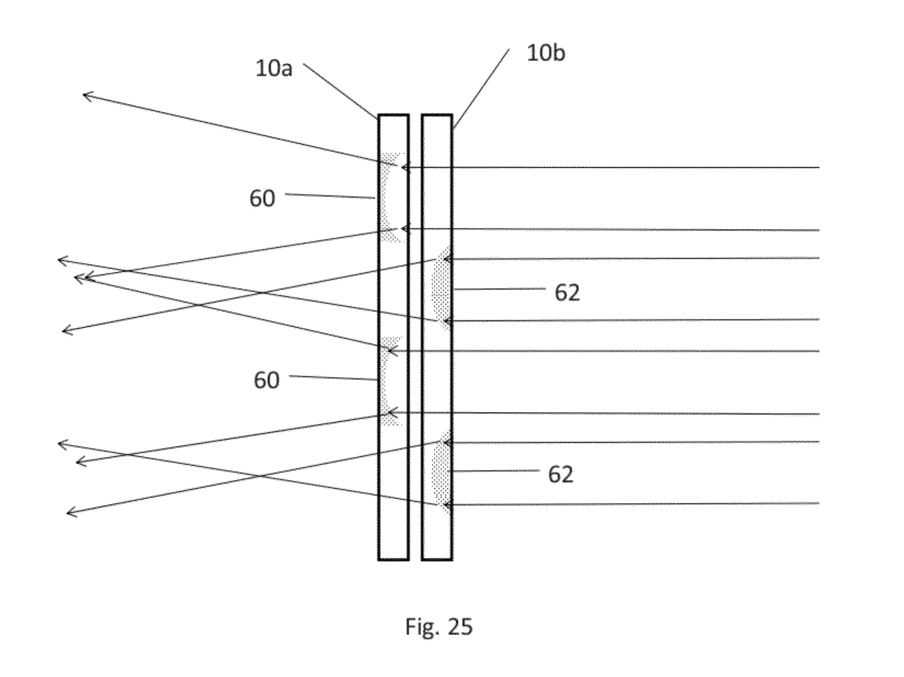

FIG. 25 illustrates scattering by panels with lenses according to an embodiment of the invention. Panel 10a includes plano-concave (diverging) lenses 60. Panel 10b includes plano-convex (converging) lenses 62. As shown in FIG. 25, both panels 10a and 10b cause light to scatter, such that no clear image may be visible when viewing through both panels. However, alignment of each plano-concave lens 60 with a plano-convex lens 62 may enable a ray of light to traverse panels 10a and 10b with little deviation.

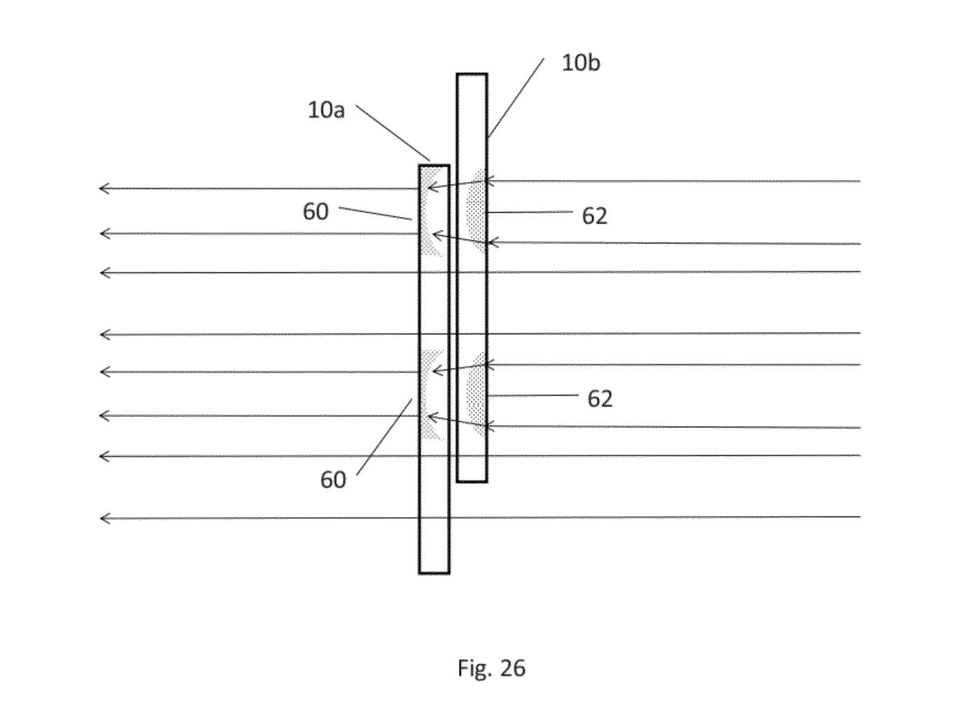

FIG. 26 shows the panels of FIG. 25 aligned such that lens on the panels compensate for one another according to an embodiment of the invention. As shown in FIG. 26, each plano-concave lens 60 of panel 10a is aligned with a plano-convex lens 62 of panel 10b. As a result, parallel rays of light remain parallel after traversing panels 10b and 10a Thus, light that traverses panels 10a and 10b may not be noticeably bent or distorted. Therefore when so aligned, a scene may be viewed via aligned panels 10a and 10b without, or with minimal, visible distortion. When viewing a scene via the panels as aligned in FIG. 26, all regions of the window may be equally transparent. In this alignment, the aligned panels may not have any nontransparent (opaque or translucent regions, as may exist, for example, in the window and alignment illustrated in FIG. 3 or FIG. 9. Thus, a scene may be visible via the aligned panels of FIG. 26 without any visible blurring (e.g. haze-like) or darkening effects.

In accordance with other embodiments of the invention, each panel 10a or 10b may include both converging and diverging lenses arranged such that opposite types of lenses may be aligned with one another. The converging and diverging lenses need not have one planar side. The lenses may be arranged in a two-dimensional pattern of axially symmetric (or truncated axially symmetric) lenses.

Another embodiment includes providing a predetermined distance (gap) between the two layers. This may create a situation in which looking in perpendicular angle at the window with these layers may show, in a closed opaque or translucent state, the desired effect of being closed. However, a slight deviation of the perpendicular angle may allow image penetration.

For example, these phenomena may lead to disruption of the image in direct angle (180 degrees) to the object viewed. This effect “moves” with the eye going up and down along the window height (assuming the lines are horizontal). So the observer is never allowed to see what is directly in front of his expected view. This also may create a kinetic imaging effect, where the obstructed view is moving with the observer's eye, up or down, to force an obstructed view as the observer tries to avoid it.

As another example, the image light is allowed to enter the eye of the observer (viewer, user) at an angle determined by the gap between the layers. If the gap is small enough, the angle may be large enough to allow viewing only of “not important” fields of view, while direct viewing of “important fields of view” is always obstructed.

On the other hand, a larger gap may allow a repeated pattern of obstructed view (starting at zero angle) followed by “open” image view, followed by an obstructed view. This cycle repetition is dependent on the gap width. The wider the gap the higher the cycle frequency (and the smaller the bands).

Also, this repeated cycle, as it is dependent on the angle of view, may vary by the distance of the observer from the glass, getting lower frequencies of obstructed and clear image from a large distance (up to completely obstructed view of the whole glass area), and higher frequency from a short distance.

For example, with a repeated horizontal lines of width and gap between lines of approximately 0.5 mm, and the gap between layers of about 0.4 mm, a band of obstructed image view would be about 3 cm in width followed by a similar band of clear image view area, when observed at a distance of about 1 meter from the glass. When moving the eye up and down (vertically), the bands move with the eye, obstructing and exposing approximately the same image areas, e.g., no change in image area by moving the eye vertically. However, moving away from the glass would increase the bands width their wavelength (peak to peak band distance) and decrease their frequency. Getting closer to the glass would do the opposite.

A layer is made to expand or contract at a different rate than the other layers, depending on temperature changes. One layer may be made to move over the other layer by means of an apparatus (e.g., a bi-metal) that expands or contracts based on temperature. One layer may be made to move over the other layer by means of an apparatus that is activated by light intensity (e.g., photo detector). One layer may be made to move over the other layer by means of an apparatus that is activated by change in temperature (e.g., heat-detector).

Production means that are used to apply nontransparent ink type material on a transparent substrate may include using a flexographic printing method.

The areas that are transparent, translucent, or opaque may not be parallel to each other, may be curved, or may form a repeated pattern.

A layer of translucent material may include areas that are cut out to make it transparent, and may be attached to a substrate.

A high optical density material may have an optical density in the range of 0.1 to 10.0.

The high-density material may have a different line width in each layer, or within the layer (to make variable density windows, e.g., brighter at the top than at the bottom).

The nontransparent material in the various layers or within a single layer may be composed of different materials (and similarly for the transparent material). Such use of different materials may enable providing the window or layer with variable optical density, privacy, or spectral transmission and reflection options (e.g. brighter and less transmissive of heat near the top, scattering for privacy at the bottom).

The high optical density areas may be coated in reflective material on the exterior surface to reflect light and heat, and a second coating of a different color (and texture) may be deposited on the interior surface. The high optical density areas may be coated in reflective material on the interior surface. The high optical density areas may be coated in reflective material on the exterior surface to simulate a one way mirror, so the window appearance may be of mirror from the outside, and dimmed image of the outside scenery from the inside of the building.

A system may incorporate a dial button, switch, a lever, or electrical switch, to move one layer over another.

The panes (layers) may be made of different materials (such as polyester, photographic films, Plexiglas® material, polycarbonates, etc.).

The high optical density areas may be coated in a diffuse material that has heat absorbing or reflecting properties, to reflect or absorb the heat energy, to reduce the heat load on the building interiors. The high optical density areas may be coated in a diffuse material that has heat absorbing or reflecting properties, to reflect or absorb the heat energy. In, for example, the stationary layer, a heat absorbing layer may be used (to allow heating of the glass in the cold winter months where the window may be mostly in open state exposing mainly the stationary layer). In the moving layer a heat reflecting material may be used to reflect the heat when the layer is exposed to the outside heat and light (which would be mainly in the summer months). This way the building interiors may be warmed up in the cold season, and cooled down in the hot season.

An (e.g., insulating) layer may be put over and between the sides of the panes. Such layer may be connected to the stationary pane, and to the moving pane to cover the gap between the panes. Such a layer can be made of elastic material such as latex. It may be located in the (unexposed) invisible parts of the panes, covered by the window frame. Alternatively, if such layer is made of transparent material it may completely cover the whole panes and some or all the related equipment.

One or more layers may have a pattern (created by adding or subtracting ink (optically modifying material) from the repeated pattern) that is not seen in one state and is revealed during the transition to the other state due to the motion of the pane. The pattern can be of any color, and combinations of colors can be made with patterns on both panels, or multiple panels, that by their movement create the desired patterns.

One or more layers have a pattern (created by adding or subtracting ink (optically modifying material) from the repeated pattern) that is seen in one state and is changing its appearance during the transition to, and reaching, the other state, due to the motion of the pane.

A gap between the layers may be set to alter the light modulation of the whole glass pane in a desired manner. For example, this may cause bands to be formed which alternate the modulation of image transfer, allowing or not allowing an image to pass through. For example, the frequency of the bands may increase, with a smaller width (or area) of each area of optically modifying material, as the gap between the layers (panes) is widened, and as a distance from the eye to the window is decreased.

Different embodiments are disclosed herein. Features of certain embodiments may be combined with features of other embodiments; thus certain embodiments may be combinations of features of multiple embodiments. The foregoing description of the embodiments of the invention has been presented for the purposes of illustration and description. It is not intended to be exhaustive or to limit the invention to the precise form disclosed. It should be appreciated by persons skilled in the art that many modifications, variations, substitutions, changes, and equivalents are possible in light of the above teaching. It is, therefore, to be understood that the appended claims are intended to cover all such modifications and changes as fall within the true spirit of the invention.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A window with variable transparency to light, the window comprising two layers, the layers being arranged substantially parallel to one another, each layer including a pattern of a plurality of alternating transparent and nontransparent areas, at least one of the layers being movable back and forth in one direction so as to vary the transparency of the window.

2. The window of claim 1, wherein the pattern comprises a plurality of parallel alternating transparent and nontransparent stripes, each stripe being oriented perpendicular to the direction.

3. The window of claim 1, wherein the pattern comprises a plurality of alternating transparent and nontransparent parallelograms.

4. The window of claim 3, wherein the parallelograms comprise rectangles.

5. The window of claim 1, wherein the nontransparent areas comprise a nontransparent material selected from a group of nontransparent materials consisting of: an etched transparent material, a polymer, a painted transparent material, ink deposited on a transparent material, a lamination layer, a metal, and a deposited metal layer.

6. The window of claim 1, comprising a mechanism for moving the moveable layer, the mechanism comprising at least one mechanism selected from a group of mechanisms consisting of a slidable wedge, a rotatable ellipse, an eccentrically mounted disk, an electromagnet, an electric motor, a piezoelectric motor, a bimetallic strip, and a spring.

7. The window of claim 1, wherein at least one side of at least one of the transparent or nontransparent areas is at least partially reflecting to radiation in a selected spectral region.

8. The window of claim 1, wherein at least one side of at least one of the transparent or nontransparent areas is configured to generate electricity from incident radiation.

9. The window of claim 8, wherein the side that is configured to generate electricity comprises a photovoltaic cell.

10. The window of claim 1, wherein at least one of the transparent areas on one of the layers comprises a material that is different than a material comprised by at least one of the transparent areas on another of the layers, or wherein at least one of the nontransparent areas on one of the layers comprises a material that is different than a material comprised by at least one of the nontransparent areas on another of the layers.

11. The window of claim 1, wherein the transparent or nontransparent areas comprise a transparent material selected from a group of transparent materials consisting of glass, polymer, resin, and air.

12. The window of claim 1, wherein the nontransparent areas comprise a nontransparent material deposited on at least one side of a transparent substrate using a deposition method selected from a group of deposition methods consisting of: printing, offset printing, flexographic printing, inkjet printing, lamination, vacuum deposition, sputtering, painting, and coating.

13. The window of claim 1, wherein at least one of the transparent or nontransparent areas is spectrally selectively transmissive.

14. The window of claim 1, comprising a seal.

15. The window of claim 14, wherein the seal comprises a sealing material selected from a group of sealing materials consisting of: rubber, latex, resin, silicone, polymer, and nylon.

16. The window of claim 1, wherein the nontransparent areas of one of the layers are translucent, while the nontransparent areas of another of the layers are opaque.

17. The window of claim 1, wherein the layers are substantially identical to one another.

18. The window of claim 1, wherein at least one of the layers is reversible.

19. The window of claim 1, wherein the pattern varies across the layer.

20. The window of claim 1, wherein the nontransparent areas comprise converging and diverging lenses, such that when a converging lens on one layer is aligned with a diverging lens on another layer, a scene may be viewed substantially undistorted via the aligned lenses.
